(19) United States
(12) Patent Application Publication
(10) Pub. No.: US 2017/0117142 A1
(43) Pub. Date: Apr. 27, 2017

(54) Organic Germanium Amine Compound and Method for Depositing Thin Film Using the Same

(71) Applicant: Eugene Technology Materials Co., Ltd., Gyeonggi-do (KR)

(72) Inventors: Geun Su Lee, Gyeonggi-do (KR); Yun Yeong Lee, Gyeonggi-do (KR); Yeong Min Lee, Gyeonggi-do (KR)

(21) Appl. No.: 15/126,876

(22) PCT Filed: Mar. 18, 2015
(86) PCT No.: PCT/KR2015/002628

§ 371 Date: Sep. 16, 2016

(30) Foreign Application Priority Data
Mar. 18, 2014 (KR) 10-2014-0031828

(51) Int. Cl. H01L 21/02; C07F 7/30; C23C 16/455; C23C 16/34; C23C 16/40

(52) U.S. Cl. CPC H01L 21/02205; C23C 16/34; C23C 16/407; C23C 16/45553; H01L 21/02271; H01L 21/0228; H01L 21/02112; H01L 21/02181; H01L 21/02189; H01L 21/02186; C07F 7/30

(57) ABSTRACT

Disclosed are an organic germanium amine compound represented by chemical formula 1, recited in claim 1, and a film-forming method using the compound as a precursor. When the compound according to the present invention is used as a precursor, a germanium oxide film, a germanium nitride film, a metal germanium oxide film, a metal germanium nitride film, or the like, can be effectively formed by deposition.

### TECHNICAL FIELD

The present invention relates to an organic germanium amine compound and a method of depositing a thin film using the same. More particularly, the present invention relates to an organic germanium amine compound capable of efficiently forming a germanium-containing thin film having useful characteristics making it suitable for use as a passivation layer, an interlayer insulating layer, a capacitor dielectric layer, etc., such as a germanium oxide film, a metal germanium oxide film, a germanium nitride film, etc., during manufacture of a semiconductor device, and a method of depositing a thin film using the same.

### BACKGROUND ART

In a process of manufacturing a semiconductor device, a silicon-containing thin film, for example, a silicon film, a silicon nitride film, a silicon carbon nitride film, a silicon oxide film, a silicon oxynitride film, etc., plays a very important role. In particular, the silicon oxide film and the silicon nitride film play an important role as a passivation layer, an interlayer insulating layer, a capacitor dielectric layer, etc.

At present, a variety of silicon precursors used to form the silicon-containing film are actively being developed. Chain-type aminosilanes silicon precursors, which are widely used at present, have a high molecular weight, but have a low boiling point and low affinity and binding ability to lower structures such as a silicon oxide film, a silicon nitride film, various metal wiring layers, etc. (hereinbelow, simply referred to as ‘lower structure’), such that there are disadvantages that the deposition rate of the silicon film is low, and the porosity of the deposited silicon film is high, resulting in low density of the silicon film and low deposition uniformity of the deposited silicon film.

Further, for example, to form the silicon nitride film, a silicon precursor and a nitrogen source gas are used. However, when these two sources are used at the same time, a high process temperature of about 500˜700° C. is required, which causes adverse effects in highly integrated devices, and poor step coverage.

### DETAILED DESCRIPTION OF THE INVENTION

### Technical Problem

Accordingly, in order to solve the above problems of the prior art in a manufacturing process of a semiconductor device, an object of the present invention is to provide a novel organic germanium amine compound having germanium as a central atom, which has a high boiling point to exhibit excellent thermal stability and has excellent affinity and binding ability to a lower structure, thereby efficiently forming a germanium-containing film having excellent thin film characteristics, thickness uniformity, and step coverage.

Another object of the present invention is to provide a film forming method of forming the germanium-containing film with excellent thin film characteristics, thickness uniformity, and step coverage, by using the organic germanium amine compound as a precursor.

### Technical Solution

In order to achieve an object of the present invention, an aspect of the present invention provides an organic germanium amine compound represented by the following Chemical Formula 1:

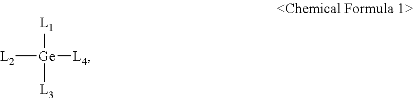

wherein L₁, L₂, L₃, and L₄ are each independently selected from a hydrogen atom, an alkyl group having 1 to 10 carbon atoms, an aryl group having 6 to 12 carbon atoms, an alkylamine group having 1 to 10 carbon atoms, a dialkylamine group having 1 to 10 carbon atoms, an arylamine group having 6 to 12 carbon atoms, an aralkylamine group having 7 to 13 carbon atoms, a cyclic amine group having 3 to 10 carbon atoms, a heterocyclic amine group having 3 to 10 carbon atoms, and an alkylsilylamine group having 2 to 10 carbon atoms.

In an embodiment of the present invention, the compound of Chemical Formula 1 may be represented by the following Chemical Formula 2:

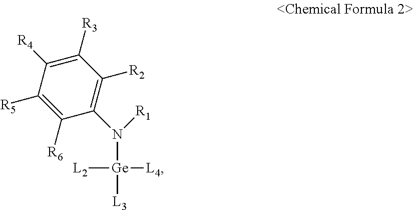

wherein L₂, L₃ and L₄ are the same as defined in claim 1, and R¹, R², R³, R⁴, R⁵, and R⁶ are each independently selected from a hydrogen atom, an alkyl group having 1 to 10 carbon atoms, an aryl group having 6 to 12 carbon atoms, an aralkyl group having 7 to 13 carbon atoms, and an alkylsilyl group having 2 to 10 carbon atoms.

In an embodiment of the present invention, the compound of Chemical Formula 2 may be represented by the following Chemical Formula 3:

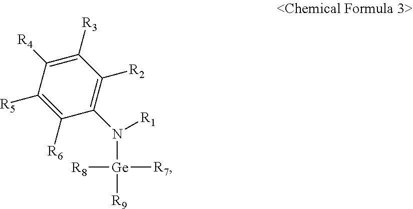

wherein R₁, R₂, R₃, R₄, R₅, and R₆ are each independently selected from a hydrogen atom and an alkyl group having 1 to 10 carbon atoms, and R₇, R₈, and R₉ are each independently selected from a hydrogen atom, an alkyl group having 1 to 10 carbon atoms, an aryl group having 6 to 12 carbon atoms, an alkylamine group having 1 to 10 carbon atoms, a dialkylamine group having 1 to 10 carbon atoms, an arylamine group having 6 to 12 carbon atoms, an aralkylamine group having 7 to 13 carbon atoms, a cyclic amine group having 3 to 10 carbon atoms, a heterocyclic amine group having 3 to 10 carbon atoms, and an alkylsilylamine group having 2 to 10 carbon atoms.

In an embodiment of the present invention, the compound of Chemical Formula 3 may be represented by the following Chemical Formula 4:

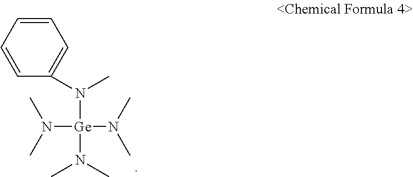

In another embodiment of the present invention, the compound of Chemical Formula 3 may be represented by the following Chemical Formula 5:

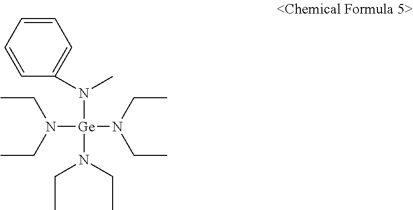

In still another embodiment of the present invention, the compound of Chemical Formula 3 may be represented by the following Chemical Formula 6:

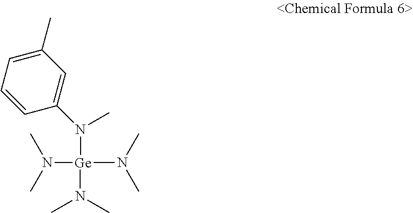

In order to achieve another object of the present invention, another aspect of the present invention provides a method of forming a film, the method including forming a germanium-containing film on a substrate by a deposition process using the organic germanium amine compound according to an aspect of the present invention as a precursor.

In a specific embodiment, the deposition process may be an atomic layer deposition (ALD) process or a chemical vapor deposition (CVD) process, for example, a metal organic chemical vapor deposition (MOCVD) process.

In a specific embodiment, the deposition process may be performed at 50 to 500° C.

In a specific embodiment, thermal energy, plasma, or an electrical bias may be applied to the substrate during the deposition process.

In a specific embodiment, the organic germanium amine compound is mixed with one or more carrier gases or diluent gases selected from argon (Ar), nitrogen (N₂), helium (He), and hydrogen (H₂), and the mixture is transported to the substrate, followed by the deposition process. The germanium-containing film thus formed on the substrate may be a germanium film.

In another specific embodiment, the organic germanium amine compound is mixed with one or more reaction gases selected from water vapor (H₂O), oxygen (O₂) and ozone (O₃), and the mixture is transported to the substrate, or the reactions gases and the organic germanium amine compound are transported separately to the substrate, followed by the deposition process. The germanium-containing film thus formed on the substrate may be a germanium oxide film or a metal germanium oxide film including at least one material selected from germanium oxide (GeₓO_{y}), hafnium germanium oxide (HfₓGe_{y}O_{z}), zirconium germanium oxide (ZrₓGe_{y}O_{z}), and titanium germanium oxide (TiₓGe_{y}O_{z}).

In still another specific embodiment, the organic germanium amine compound is mixed with one or more reaction gases selected from ammonia (NH₃), hydrazine (N₂H₄), nitrogen dioxide (NO₂) and nitrogen (N₂) plasma, and the mixture is transported to the substrate, or the reactions gases and the organic germanium amine compound are transported separately to the substrate, followed by the deposition process. The germanium-containing film thus formed on the substrate may be a germanium nitride film or a metal germanium nitride film including at least one material selected from germanium nitride (GeₓN_{y}), hafnium germanium nitride (HfₓGe_{y}N_{z}), zirconium germanium nitride (ZrₓGe_{y}N_{z}), and titanium germanium nitride (TiₓGe_{y}N_{z}).

In an embodiment of the present invention, the deposition process may include, for example, heating the substrate at a temperature of 50° C. to 500° C. in a vacuum, or in an active or inert atmosphere;

introducing the organic germanium amine compound heated at a temperature of 20° C. to 100° C. on the substrate,

forming an organic germanium amine compound layer on the substrate by adsorbing the organic germanium amine compound onto the substrate; and

forming a germanium-containing film on the substrate by applying thermal energy, plasma, or an electrical bias to the substrate to decompose the organic germanium amine compound.

### Advantageous Effects of the Invention

An organic germanium amine compound according to an aspect of the present invention is in a liquid state at room temperature, and has a smaller molecular size but a higher boiling point and excellent thermal stability. Further, when this compound forms, for example, a metal germanium complex film, it has a decomposition temperature similar to that of a metal precursor compound serving as a metal source, for example, a Zr compound, thereby having a narrow temperature window within which a deposition process may be performed. Since the present organic germanium amine compound includes a nitrogen atom and a germanium atom having an unshared electron pair in one molecular structure, it exhibits strong affinity to the silicon substrate and metal atoms. Accordingly, when the compound according to an aspect of the present invention is used in a deposition process of a germanium oxide film, a germanium nitride film, a metal germanium oxide film, or a metal germanium nitride film, the following effects may be achieved:

(1) since a large number of molecules per unit area of the lower structure are adsorbed in the deposition process conducted at a high temperature, a deposition rate, a deposition density, and a deposition uniformity, namely, step coverage of the germanium-containing film, may be improved.

(2) since the compound has a strong affinity to the silicon atom or metal atom in the lower structure resulting in high adhesiveness to the lower structure, the deposition rate, the deposition density, and the deposition uniformity, namely, step coverage of the germanium-containing film, may be further improved.

Accordingly, the organic germanium amine compound according to an aspect of the present invention may be efficiently applied to a semiconductor manufacturing process of depositing the germanium-containing film by a metal organic chemical vapor deposition (MOCVD) process and an atomic layer deposition (ALD) process. Further, the organic germanium amine compound according to an aspect of the present invention is used to efficiently form the germanium-containing film having useful characteristics making it suitable for use as a passivation layer, interlayer insulating layer or capacitor dielectric layer such as a germanium oxide film, a germanium nitride film, a metal germanium oxide film, a metal germanium nitride film, etc., during manufacture of a semiconductor device.

### DESCRIPTION OF THE DRAWINGS

FIG. 1 shows a differential scanning calorimetry (DSC) thermogram and a thermogravimetric analysis (TGA) thermogram together in one graph, each thermogram obtained in a test of tris(dimethylamine)methylanilino germanium(IV) prepared in Example 1;

FIG. 2 shows a DSC thermogram and a TGA thermogram together in one graph, each thermogram obtained in a test of tris(dimethylamino)methyl-m-toluidino germanium(IV) prepared in Example 3; and

FIG. 3 shows the deposition result obtained in a test of tris(dimethylamine)methylanilino germanium(IV) prepared in Experimental Example 1.

### BEST MODE

Hereinafter, an organic germanium amine compound according to specific embodiments of the present invention and a method of forming a film, for example, of depositing a thin film, using the same will be described in detail.

An organic germanium amine compound according to an aspect of the present invention is represented by the following Chemical Formula 1:

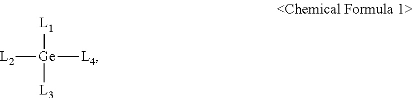

wherein L₁, L₂, L₃ and L₄ are each independently selected from a hydrogen atom, an alkyl group having 1 to 10 carbon atoms, an aryl group having 6 to 12 carbon atoms, an alkylamine group having 1 to 10 carbon atoms, a dialkylamine group having 1 to 10 carbon atoms, an arylamine group having 6 to 12 carbon atoms, an aralkylamine group having 7 to 13 carbon atoms, a cyclic amine group having 3 to 10 carbon atoms, a heterocyclic amine group having 3 to 10 carbon atoms, and an alkylsilylamine group having 2 to 10 carbon atoms.

C, Si, and Ge, which are Group IV elements, have a band gap of 5.5 eV, 1.11 eV, and 0.67 eV, respectively. The band gap refers to the energy difference between the highest energy level of the valence band where there are electrons and the lowest energy level of the conduction band where there are no electrons in insulators or semiconductors. If a material has a small band gap, it may be a good semiconductor material because current may be transferred by applying a low voltage. The compound represented by Chemical Formula 1 is a new type of precursor having germanium with a small band gap as a central atom. In particular, the compound represented by Chemical Formula 1 is in a liquid state at room temperature, and has a smaller molecular size but a higher boiling point and excellent thermal stability. Further, when this compound forms, for example, a metal germanium complex film, the compound has a decomposition temperature similar to that of a metal precursor compound serving as a metal source, for example, a Zr compound, thereby having a narrow temperature window within which a deposition process may be performed. Since the compound includes a nitrogen atom and a germanium atom having an unshared electron pair in one molecular structure, it exhibits strong affinity to the silicon substrate and metal atoms. Accordingly, when the compound according to an aspect of the present invention is used in a deposition process of a germanium-containing film, a large number of molecules per unit area of the lower structure are adsorbed, and therefore, a deposition rate, a deposition density, and a deposition uniformity, namely, step coverage of the germanium-containing film, may be improved. Further, the compound has a strong affinity to the silicon atom or metal atom in the lower structure resulting in high adhesiveness to the lower structure, and therefore, the deposition rate, the deposition density, and the deposition uniformity, namely, step coverage of the germanium-containing film may be further improved.

Preferably, the compound of Chemical Formula 1 may be a compound represented by the following Chemical Formula 2:

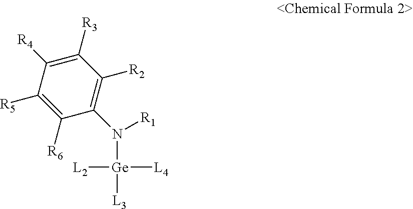

wherein L₂, L₃ and L₄ are the same as defined in claim 1, and R¹, R², R³, R¹, R⁵, and R⁶ are each independently selected from a hydrogen atom, an alkyl group having 1 to 10 carbon atoms, an aryl group having 6 to 12 carbon atoms, an aralkyl group having 7 to 13 carbon atoms, and an alkylsilyl group having 2 to 10 carbon atoms.

More preferably, the compound of Chemical Formula 2 may be a compound represented by the following Chemical Formula 3:

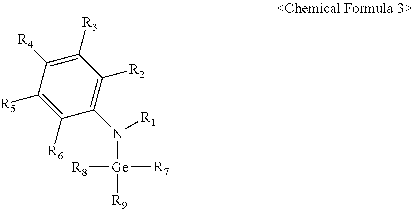

wherein R₁, R₂, R₃, R₄, R₅, and R₆ are each independently selected from a hydrogen atom and an alkyl group having 1 to 10 carbon atoms, and R₇, R₈, and R₉ are each independently selected from a hydrogen atom, an alkyl group having 1 to 10 carbon atoms, an aryl group having 6 to 12 carbon atoms, an alkylamine group having 1 to 10 carbon atoms, a dialkylamine group having 1 to 10 carbon atoms, an arylamine group having 6 to 12 carbon atoms, an aralkylamine group having 7 to 13 carbon atoms, a cyclic amine group having 3 to 10 carbon atoms, a heterocyclic amine group having 3 to 10 carbon atoms, and an alkylsilylamine group having 2 to 10 carbon atoms.

A specific example of the compound of Chemical Formula 3 may be an organic germanium amine compound represented by the following Chemical Formula 4, 5 or 6:

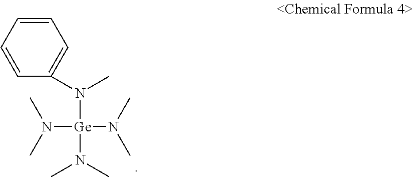

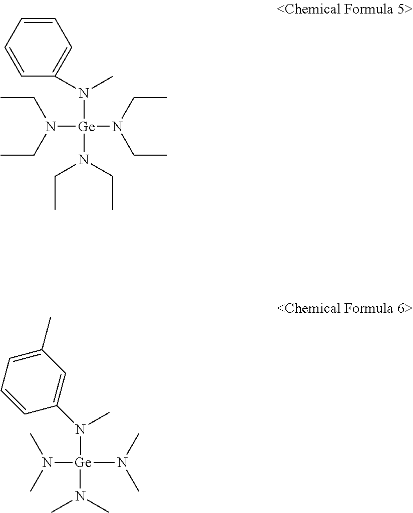

A preparation method of the compounds of Chemical Formulae 1 to 6 according to an aspect of the present invention is not particularly limited, and the compounds may be prepared by a variety of methods.

The compound of Chemical Formula 4 may be prepared by, for example, Reaction Scheme 1. Referring to the following Reaction Scheme 1, a product resulting from a first stage substitution reaction of tetrachlorogermanium and a secondary amine compound, N-methylaniline, is subjected to a second stage substitution reaction with dimethylamine to obtain the desired compound represented by Chemical Formula 4.

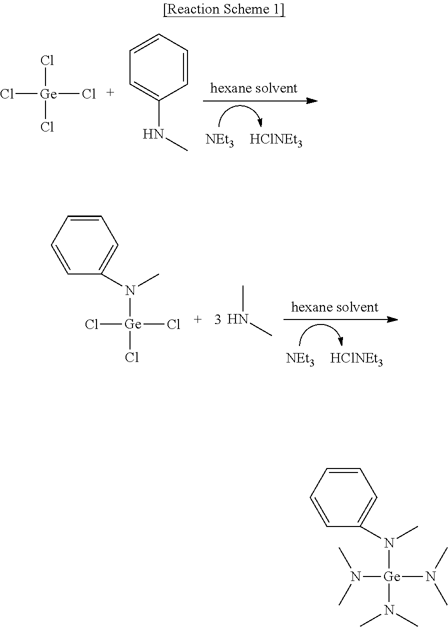

The compound of Chemical Formula 6 may be obtained by using N-methyl-m-toluidine instead of N-methylaniline in the first stage substitution reaction of Reaction Scheme 1.

The compound of Chemical Formula 5 may be prepared by, for example, Reaction Scheme 2. Referring to the following Reaction Scheme 2, a product resulting from a first stage substitution reaction of tetrachlorogermanium and a secondary amine compound, N-methylaniline, is subjected to a second stage substitution reaction with diethylamine to obtain the desired compound represented by Chemical Formula 5.

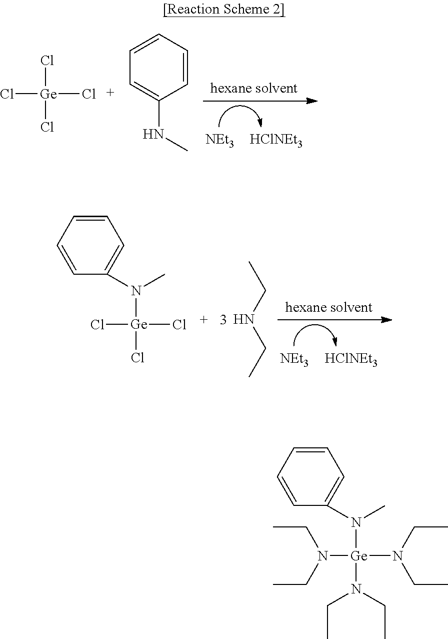

The first stage substitution reactions in the chemical reactions according to Reaction Schemes 1 and 2 may be performed in a non-polar solvent such as pentane, hexane, benzene, etc. or a polar solvent such as diethylether, tetrahydrofuran (THF), methylal, etc. The first substitution reactions may be generally performed at a reaction temperature of 0° C. 30° C., but preferably, at a reaction temperature of 0° C.˜20° C., and for about 1 hour to about 100 hours, but preferably, for about 3 hours to about 72 hours. The second stage substitution reactions may be performed in a non-polar solvent such as pentane, hexane, benzene, etc. or a polar solvent such as diethylether, tetrahydrofuran, methylal, etc. The second substitution reactions may be generally performed at a reaction temperature of 0° C.˜30° C., but preferably, at a reaction temperature of 0° C.˜10° C., and for about 6 hours to about 50 hours, but preferably, for about 6 hours to about 20 hours. Generally, in the first and second stage substitution reactions in the chemical reactions according to Reaction Schemes 1 and 2, the amount of the reaction solvent used may be in a range such that the total concentration of the reaction reagents in the reaction solvent is about 10% by weight to about 50% by weight, but preferably, about 20% by weight to about 40% by weight. To collect hydrochloric acid generated in the first and second stage substitution reactions, a tertiary amine, triethylamine (TEA) or trimethylamine (TMA) may be preferably used.

The method of forming a film according to another aspect of the present invention is a method of forming a film including forming a germanium-containing film on a substrate by a deposition process using the organic germanium amine compound according to an aspect of the present invention as a precursor.

The deposition process may be an atomic layer deposition (ALD) process or a chemical vapor deposition (CVD) process, for example, a metal organic chemical vapor deposition (MOCVD) process. The deposition process may be performed at 50° C. to 500° C.

For example, the organic germanium amine compound is mixed with one or more carrier gases or diluent gases selected from argon (Ar), nitrogen (N₂), helium (He), and hydrogen (H₂), and the mixture is transported to the substrate, followed by the deposition process. The germanium-containing film thus formed on the substrate may be a germanium film.

For example, the organic germanium amine compound according to the present invention is used as a precursor to form a Ge seed layer on the substrate by deposition, and this method of using the Ge seed layer may be used to improve many problems of the previous method of using a polysilicon seed layer. That is, the Ge seed layer formed by using the organic germanium amine compound according to the present invention is expected to improve a surface roughness problem of polysilicon upon a deposition process of thin polysilicon, and is also expected to improve a problem of void generation within the polysilicon film upon a gap fill process of polysilicon.

For example, the organic germanium amine compound is mixed with one or more reaction gases selected from water vapor (H₂O), oxygen (O₂) and ozone (O₃), and the mixture is transported to the substrate, or the reaction gases are transported to the substrate, separately from the organic germanium amine compound, followed by the deposition process. The germanium-containing film thus formed on the substrate may be a germanium oxide film or a metal germanium oxide film including at least one material selected from germanium oxide (GeₓO_{y}), hafnium germanium oxide (HfₓGe_{y}O_{z}), zirconium germanium oxide (ZrₓGe_{y}O_{z}), and titanium germanium oxide (TiₓGe_{y}O_{z}). For example, the organic germanium amine compound is mixed with one or more reaction gases selected from ammonia (NH₃), hydrazine (N₂H₄), nitrogen dioxide (NO₂) and nitrogen (N₂) plasma, and the mixture is transported to the substrate, or the reaction gases are transported to the substrate, separately from the organic germanium amine compound, followed by the deposition process. The germanium-containing film thus formed on the substrate may be a germanium nitride film or a metal germanium nitride film including at least one material selected from germanium nitride (GeₓN_{y}), hafnium germanium nitride (HfₓGe_{y}N_{z}), zirconium germanium nitride (ZrₓGe_{y}N_{z}), and titanium germanium nitride (TiₓGe_{y}N_{z}).

The germanium oxide film, metal germanium oxide film, germanium nitride film, or metal germanium nitride film may be usefully used as, for example, a dielectric layer upon formation of a capacitor during a process of manufacturing a dynamic random access memory (DRAM) device and a phase-change random access memory (PRAM) device.

In the specific deposition process described above, when the organic germanium amine compound is transported to the substrate, for example, the organic germanium amine compound may be transported to the substrate by a method of bubbling, or by using a vapor-phase mass flow controller, or by a method of direct liquid injection (DLI), or by dissolving the compound in an organic solvent and transporting the resultant solution in a liquid state. In this regard, in order to improve the deposition efficiency, thermal energy, plasma, or an electrical bias may be applied to the substrate during the deposition process. Specifically, the deposition process may include, for example, heating the substrate at a temperature of 50° C. to 500° C. in a vacuum, or active or inert atmosphere; introducing the organic germanium amine compound heated at a temperature of 20° C. to 100° C. on the substrate; forming an organic germanium amine compound layer on the substrate by adsorbing the organic germanium amine compound onto the substrate; and forming a germanium-containing film on the substrate by applying the thermal energy, plasma, or electrical bias to the substrate to decompose the organic germanium amine compound.

In this regard, a time taken for forming the organic germanium amine compound layer on the substrate may be less than 1 minute. An excess amount of the organic germanium amine precursor compound that is not adsorbed onto the substrate is preferably removed by using one or more inert gases such as argon (Ar), nitrogen (N₂) and helium (He). A time taken for removing an excess amount of the precursor may be less than 1 minute. Further, to remove excess amounts of reaction gases and by-products produced during the process, one or more inert gases such as argon (Ar), nitrogen (N₂) and helium (He) may be introduced into a chamber for less than 1 minute.

Since the organic germanium amine compound according to the present invention is in a liquid state at room temperature and is highly volatile while having high thermal stability and a high boiling point, it may be used as a precursor in a CVD process or an ALD process upon manufacturing a semiconductor device to efficiently form a germanium-containing film having useful characteristics making it suitable for use as a passivation layer, an interlayer insulating layer, or a capacitor dielectric layer, such as a germanium oxide film, a germanium nitride film, a metal germanium oxide film, a metal germanium nitride film, etc.

Hereinafter, the organic germanium amine compound according to the present invention will be described in more detail with reference to the following Examples. However, these Examples are for illustrative purposes only, and the present invention is not intended to be limited by the following Examples.

In the following Examples, all synthetic steps were conducted by using standard Schlenk vacuum line techniques, and all syntheses were performed under a nitrogen gas atmosphere. Tetrachlorogermanium(V) (GeCl₄), triethylamine (TEA), dimethylamine (DMA), N-methylaniline, diphenylamine, and diethylamine (DEA) used in the experiments were purchased from Aldrich. As a solvent used in reactions, anhydrous hexane or diethyl ether purified by refluxing over sodium/benzophenone for 24 hours or longer under an argon atmosphere was used. Further, each of N-methylaniline, TEA and DEA was stirred for 24 hours in the presence of CaH₂ to completely remove residual water from them and then was purified under reduced pressure and used. GeCl₄ subdivision was carried out in a nitrogen-purged glove box.

Structural analysis of synthesized compounds was performed using a JEOL JNM-ECS 400 MHz NMR spectrometer (¹H-NMR 400 MHz). An NMR solvent, benzene-d₆, was used after completely removing residual water therefrom by stirring with CaH₂ for one day.

### MODE OF THE INVENTION

### Example 1: Preparation of tris(dimethylamine)methylanilino germanium(IV) ((Me₂N)₃GeNC₇H₈)

200 ml of anhydrous hexane and 5.59 g (0.0552 mol) of TEA were added to a 500-ml first branched round flask, and then 4.23 g (0.0394 mol) of N-methylaniline was added again. While the internal temperature of the first branched round flask was maintained at 0° C., 8.46 g (0.0394 mol) of GeCl₄ was slowly added using a dropping funnel. A white salt began to be formed by the addition of GeCl₄. After complete addition of GeCl₄, the internal temperature of the first flask was raised to 30° C., followed by further stirring for about 4 hours.

During the stirring for about 4 hours, 150 ml of anhydrous hexane and 13.17 g (0.1302 mol) of TEA were added to a 500-ml second branched round flask, and then 16.01 g (0.355 mol) of DMA gas was slowly added thereto. While the internal temperature of the 500-ml first branched round flask where the white salt was formed was maintained at 0° C., the TEA and DMA-dissolved hexane solution in the second flask was slowly added to the first flask using a dropping funnel. As a result, a white salt was formed in the first flask. Thereafter, the internal temperature of the first flask was raised to 30° C., followed by further stirring for about 15 hours. After completion of the reaction, the salt was completely removed by filtration under reduced pressure. Fractional distillation was conducted under reduced pressure to obtain 8 g of a colorless product (yield: 80%).

Boiling point (b.p): 83° C. at 0.8 torr.

¹H-NMR(C₆D₆): δ 2.56 ([(CH₃)₂N]₃-Ge, d, 18H),

δ 2.82 ((CH₃)C₆H₅N—Ge, s, 3H),

δ 6.8, 7.0, 7.2 ((CH₃)C₆H₅N—Ge, m, 5H).

### Example 2: Preparation of tris(diethylamine)methylanilino germanium(IV) ((Et₂N)₃GeNC₇H₈)

200 ml of anhydrous hexane and 4.26 g (0.0421 mol) of TEA were added to a 500-ml first branched round flask, and then 4.30 g (0.0401 mol) of N-methylaniline was added again. While the internal temperature of the first branched round flask was maintained at 0° C., 8.6 g (0.0401 mol) of GeCl₄; was slowly added thereto using a dropping funnel. A white salt began to be formed by the addition of GeCl₄. After complete addition of GeCl₄, the internal temperature of the first flask was raised to 30° C., followed by further stirring for about 4 hours.

During the stirring for about 4 hours, 150 ml of anhydrous hexane and 8.52 g (0.1263 mol) of TEA were added to a 500-ml second branched round flask, and then 9.68 g (0.1353 mol) of DEA was slowly added thereto. While the internal temperature of the 500-ml first branched round flask where the white salt was formed was maintained at 0° C., the TEA and DEA-dissolved hexane solution in the second flask was slowly added to the first flask using a dropping funnel. As a result, a white salt was formed in the first flask. Thereafter, the internal temperature of the first flask was raised to 30° C., followed by further stirring for about 15 hours. After completion of the reaction, the salt was completely removed by filtration under reduced pressure. Fractional distillation was conducted under reduced pressure to obtain 7.5 g of a colorless product (yield: 75%).

Boiling point (b.p): 95° C. at 0.8 torr.

¹H-NMR (C₆D₆): δ 2.85 ([(CH₂CH₃)₂]₃N—Ge, q, 12H),

δ 1.04 ([(CH₂CH₃)₂]₃N—Ge, t, 18H),

δ 2.94 ((CH₃)C₆H₅N—Ge, s, 3H),

δ 6.8, 7.0, 7.2 ((CH₃)C₆H₅N—Ge, m, 5H).

### Example 3: Preparation of tris(dimethylamino)methyl-m-toluidino germanium(IV) ((Me₂N)₃GeNC₈H₁₀)

200 ml of anhydrous hexane and 8.46 g (0.0307 mol) of GeCl₄ were added to a 500-ml first branched round flask. While the internal temperature of the first branched round flask was maintained at 0° C., a solution obtained by adding 4.35 g (0.0307 mol) of TEA (triethylamine) and 3.72 g (0.0307 mol) of N-methyl-m-toluidine to 50 ml of anhydrous hexane was slowly added to the first round flask using a dropping funnel. A white salt began to be formed by the addition. After complete addition of the TEA and N-methyl-m-toluidine dilute solution, the internal temperature of the first flask was raised to 30° C., followed by further stirring for about 4 hours.

During the stirring for about 4 hours, 150 ml of anhydrous hexane and 36.36 ml (0.0922 mol) of n-butyllithium (n-BuLi) were added to a 500-ml second branched round flask. While the internal temperature of the second flask was maintained at 0° C., 4.16 g (0.0922 mol) of dimethylamine (DMA) gas was slowly added thereto. After complete addition, the internal temperature of the second flask was raised to 30° C., followed by further stirring for about 4 hours.

While the internal temperature of the 500-ml first branched flask including GeCl₄, TEA, and N-methyl-m-toluidine where the white salt was formed was maintained at 0° C., n-BuLi and DMA-dissolved hexane solution in the second flask was slowly added to the first flask. As a result, a lithium salt was produced. After complete addition of n-BuLi and DMA-dissolved hexane solution, the internal temperature of the first flask was raised to 30° C., followed by further stirring for about 15 hours. After completion of the reaction, the salt was completely removed by filtration under reduced pressure. Fractional distillation was conducted under reduced pressure to obtain a light yellow product (9 g, 90%).

Boiling point (b.p): 92° C. at 0.4 torr.

¹H-NMR (C₆D₆): δ 2.58 ([(CH₃)₂N]₃—Ge, d, 18H),

δ 2.86 ([(C₆H₄(CH₃))CH₃N]—Ge, s, 3H),

δ 2.29 ([(C₆H₄(CH₃))CH₃N]—Ge, s, 3H),

δ 6.6, 6.9, 7.2 ([(C₆H₄(CH₃))CH₃N]—Ge, m, 4H)

<Thermal Analysis>

Tris(dimethylamine)methylanilino germanium(IV) and tris(dimethylamino)methyl-m-toluidino germanium(IV) obtained in Examples 1 and 3 were subjected to differential scanning calorimetry (DSC) and thermogravimetric analysis (TGA).

The DSC test was conducted using a thermal analyzer (manufacturer: TA Instruments, model: TA-Q 600) in a DSC mode to measure thermal stability and thermal decomposition temperature, and the TGA test was conducted using the thermal analyzer in a TGA mode to measure the amount of residue. Test conditions for the thermal analysis are as follows:

Carrier gas: argon (Ar) gas,

Carrier gas flow rate: 100 cc/min,

Heating profile: heated from 30° C. to 500° C. at a heating rate of 10° C./min.

Amount of sample: 10 mg.

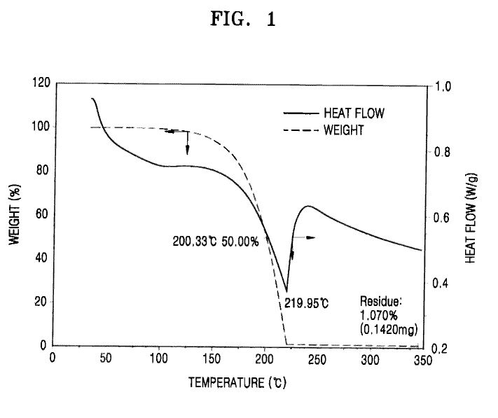

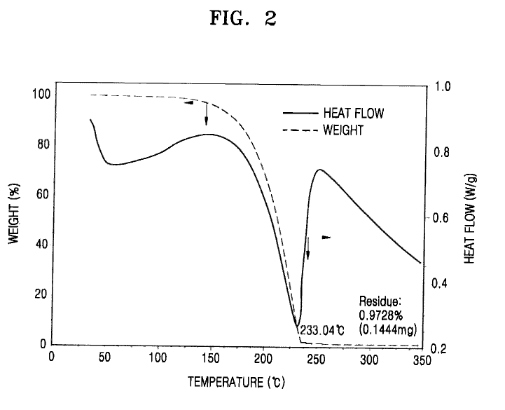

In the DSC test, the thermal decomposition temperature was determined as a temperature at a point where heat flow suddenly stops decreasing and starts increasing again upon heating according to DSC thermograms of FIGS. 1 and 2 explained below.

FIG. 1 shows a DSC thermogram and a TGA thermogram together in one graph, each thermogram obtained in a test of tris(dimethylamine)methylanilino germanium(IV) prepared in Example 1. In FIG. 1, the thermogram indicated by a thick solid line is the result obtained from the DSC test, and the thermogram indicated by a dashed line is the result obtained from the TGA test.

Referring to FIG. 1, the thermal decomposition temperature of tris(dimethylamine)methylanilino germanium(IV) was about 219.95° C. and the amount of residue was about 1.07% with respect to the initial weight, indicating very excellent thermal stability.

FIG. 2 shows a DSC thermogram and a TGA thermogram together in one graph, each thermogram obtained in a test of tris(dimethylamino)methyl-m-toluidino germanium(IV) prepared in Example 3. In FIG. 2, the thermogram indicated by a thick solid line is the result obtained from the DSC test, and the thermogram indicated by a broken line is the result obtained from the TGA test.

Referring to FIG. 2, the thermal decomposition temperature of tris(dimethylamino)methyl-m-toluidino germanium(IV) was about 233.04° C. and the amount of residue was about 0.97% with respect to the initial weight, indicating very excellent thermal stability.

### Experimental Example 1

A film formation was tested using tris(dimethylamine)methylanilino germanium(IV) prepared in Example 1 as a precursor by an atomic layer deposition (ALD) process. An inert gas, argon, was used for the purpose of purging and precursor carrying. Injection of the precursor, argon, plasma, and argon was determined as one cycle, and deposition was performed on a SiO₂ deposition thin film formed on a P-type Si(100) wafer.

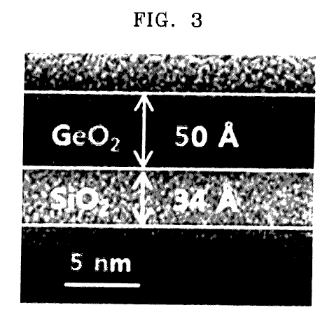

As a result, when tris(dimethylamine)methylanilino germanium(IV) was used, an ALD process could be conducted at 250° C.˜350° C., and the deposition result is given in FIG. 3. The deposition result showed that a germanium oxide film could be grown to a thickness of about 50 Å. These results suggest that the tris(dimethylamine)methylanilino germanium(IV) precursor is a candidate group suitable for deposition of germanium oxide by atomic layer deposition.

### INDUSTRIAL APPLICABILITY

According to the present invention, obtained are an organic germanium amine compound capable of efficiently forming a germanium-containing thin film having useful characteristics making it suitable for use as a passivation layer, an interlayer insulating layer, a capacitor dielectric layer, etc., such as a germanium oxide film, a metal germanium oxide film, a germanium nitride film, etc., during manufacture of a semiconductor device, and a method of depositing a thin film using the same.

1. An organic germanium amine compound represented by the following Chemical Formula 1: 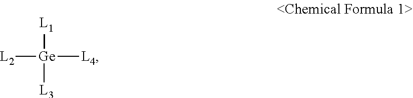
wherein L₁, L₂, L₃, and L₄ are each independently selected from a hydrogen atom, an alkyl group having 1 to 10 carbon atoms, an aryl group having 6 to 12 carbon atoms, an alkylamine group having 1 to 10 carbon atoms, a dialkylamine group having 1 to 10 carbon atoms, an arylamine group having 6 to 12 carbon atoms, an aralkylamine group having 7 to 13 carbon atoms, a cyclic amine group having 3 to 10 carbon atoms, a heterocyclic amine group having 3 to 10 carbon atoms, and an alkylsilylamine group having 2 to 10 carbon atoms.

2. The organic germanium amine compound of claim 1, wherein the compound of Chemical Formula 1 is represented by the following Chemical Formula 2: 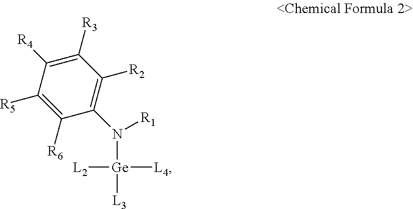
wherein L₂, L₃, and L₄ are the same as defined in claim 1, and R¹, R², R³, R⁴, R⁵, and R⁶ are each independently selected from a hydrogen atom, an alkyl group having 1 to 10 carbon atoms, an aryl group having 6 to 12 carbon atoms, an aralkyl group having 7 to 13 carbon atoms, and an alkylsilyl group having 2 to 10 carbon atoms.

3. The organic germanium amine compound of claim 2, wherein the compound of Chemical Formula 2 is represented by the following Chemical Formula 3: 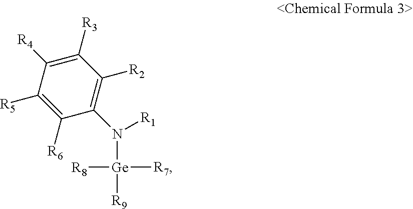
wherein R₁, R₂, R₃, R₄, R₅, and R₆ are each independently selected from a hydrogen atom and an alkyl group having 1 to 10 carbon atoms, and R₇, R₈, and R₉ are each independently selected from a hydrogen atom, an alkyl group having 1 to 10 carbon atoms, an aryl group having 6 to 12 carbon atoms, an alkylamine group having 1 to 10 carbon atoms, a dialkylamine group having 1 to 10 carbon atoms, an arylamine group having 6 to 12 carbon atoms, an aralkylamine group having 7 to 13 carbon atoms, a cyclic amine group having 3 to 10 carbon atoms, a heterocyclic amine group having 3 to 10 carbon atoms, and an alkylsilylamine group having 2 to 10 carbon atoms.

4. The organic germanium amine compound of claim 3, wherein the compound of Chemical Formula 3 is represented by the following Chemical Formula 4:

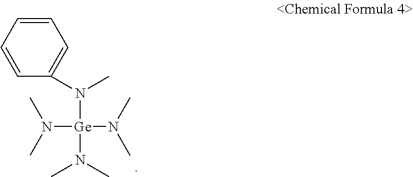

5. The organic germanium amine compound of claim 3, wherein the compound of Chemical Formula 3 is represented by the following Chemical Formula 5:

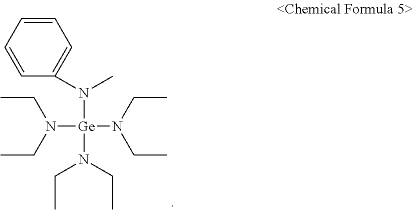

6. The organic germanium amine compound of claim 3, wherein the compound of Chemical Formula 3 is represented by the following Chemical Formula 6:

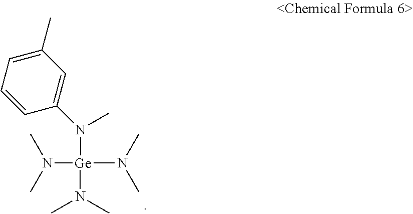

7. A method of forming a film, the method comprising forming a germanium-containing film on a substrate by a deposition process using the organic germanium amine compound according to claim 1 as a precursor.

8. The method of forming the film of claim 7, wherein the deposition process is an atomic layer deposition (ALD) process or a chemical vapor deposition (CVD) process.

9. The method of forming the film of claim 7, wherein the deposition process is performed at 50° C. to 500° C.

10. The method of forming the film of claim 7, wherein thermal energy, plasma, or an electrical bias is applied to the substrate during the deposition process.

11. The method of forming the film of claim 7, wherein the organic germanium amine compound is mixed with one or more carrier gases or diluent gases selected from argon (Ar), nitrogen (N₂), helium (He), and hydrogen (H₂), and the mixture is transported to the substrate, followed by the deposition process.

12. The method of forming the film of claim 11, wherein the germanium-containing film thus formed on the substrate is a germanium film.

13. The method of forming the film of claim 7, wherein the organic germanium amine compound is mixed with one or more reaction gases selected from water vapor (H₂O), oxygen (O₂) and ozone (O₃), and the mixture is transported to the substrate, or the reaction gases are transported to the substrate, separately from the organic germanium amine compound, followed by the deposition process.

14. The method of forming the film of claim 13, wherein the germanium-containing film thus formed on the substrate is a germanium oxide film or a metal germanium oxide film comprising at least one material selected from germanium oxide (GeₓO_{y}), hafnium germanium oxide (HfₓGe_{y}O_{z}), zirconium germanium oxide (ZrₓGe_{y}O_{z}), and titanium germanium oxide (TiₓGe_{y}O_{z}).

15. The method of forming the film of claim 14, wherein the organic germanium amine compound is mixed with one or more reaction gases selected from ammonia (NH₃), hydrazine (N₂H₄), nitrogen dioxide (NO₂) and nitrogen (N₂) plasma, and the mixture is transported to the substrate, or the reaction gases are transported to the substrate, separately from the organic germanium amine compound, followed by the deposition process.

16. The method of forming the film of claim 15, wherein the germanium-containing film thus formed on the substrate is a germanium nitride film or a metal germanium nitride film comprising at least one material selected from germanium nitride (GeₓN_{y}), hafnium germanium nitride (HfₓGe_{y}N_{z}), zirconium germanium nitride (ZrₓGe_{y}N_{z}), and titanium germanium nitride (TiₓGe_{y}N_{z}).

17. The method of forming the film of claim 7, wherein the deposition process comprises:
heating the substrate at a temperature of 50° C. to 500° C. in a vacuum, or an active or inert atmosphere;
introducing the organic germanium amine compound heated at a temperature of 20° C. to 100° C. on the substrate;
forming an organic germanium amine compound layer on the substrate by adsorbing the organic germanium amine compound onto the substrate; and
forming a germanium-containing film on the substrate by applying thermal energy, plasma, or an electrical bias to the substrate to decompose the organic germanium amine compound.
